(19) United States
(12) Patent Application Publication
(10) Pub. No.: US 2015/0271931 A1
(43) Pub. Date: Sep. 24, 2015

(54) DISPLAY APPARATUS

(71) Applicant: SAMSUNG ELECTRONICS CO., LTD., Suwon-si (KR)

(72) Inventors: Jae Hoo PARK, Suwon-si (KR); Jun Pil OH, Suwon-si (KR)

(73) Assignee: SAMSUNG ELECTRONICS CO., LTD., Suwon-si (KR)

(21) Appl. No.: 14/662,979

(22) Filed: Mar. 19, 2015

(30) Foreign Application Priority Data
Mar. 19, 2014 (KR) 10-2014-0032007

(51) Int. Cl. H05K 5/00; G09G 3/00; H05K 5/02

(52) U.S. Cl. CPC H05K 5/0017; H05K 5/0204; G09G 3/003

(57) ABSTRACT

A display apparatus including: a display configured to be transformed between a flat state and a curved state in which both lateral ends of the display protrude; and a driving device configured to transform the display between the flat state and the curved state, wherein the driving device comprises: a first movable member disposed on a first side of a back surface of the display configured to be movable in a widthwise direction of the display; a second movable member disposed on a second side of the back surface of the display configured to be movable in the widthwise direction of the display; and a driver configured to move the first movable member and the second movable member, and wherein the first movable member and the second movable member are transformed between a straight state and a curved state in accordance with transformation of the display.

### CROSS-REFERENCE TO RELATED APPLICATION(S)

This application claims the benefit of Korean Patent Application No. 10-2014-0032007, filed on Mar. 19, 2014 in the Korean Intellectual Property Office, the disclosure of which is incorporated herein by reference in its entirety.

### BACKGROUND

1. Field

One or more exemplary embodiments relate to a display apparatus including a display module, and more particularly to a display apparatus including a display module with a transformable shape.

2. Description of the Related Art

In general, display apparatuses are apparatuses including a display module on which an image is displayed. Examples of the display apparatus are televisions (TVs), monitors, and display apparatuses including a display module with an organic light-emitting diode (OLED) panel.

The OLED panel is formed of a flexible material deformable within a predetermined range. In recent years, display apparatuses in which a display panel is fixedly installed in a curved state may provide three-dimensional or immersive effects to a user even when the user watches a two-dimensional image.

However, customers may prefer a flat display module to a curved display module.

Also, although immersive feeling may be desirable for a viewer sitting at a center of the curved display panel, a viewing angle may be limited when a plurality of viewers watch the curved display panel.

In addition, since a conventional flat display panel may deliver an image more accurately than a curved display panel, the flat display panel may be more efficient for some content types than the curved display panel.

### SUMMARY

Therefore, an aspect of one or more exemplary embodiments is to provide display apparatuses using a display module selectively in a flat state or curved state.

Additional aspects of one or more exemplary embodiments will be set forth in part in the description which follows and, in part, will be obvious from the description, or may be learned by practice of the disclosure.

In accordance with one aspect of one or more exemplary embodiments, a display apparatus includes a display configured to be transformed between a flat state and a curved state in which both lateral ends of the display protrude; and a driving device configured to transform the display between the flat state and the curved state. The driving device includes: a first movable member disposed on a first side of a back surface of the display configured to be movable in a widthwise direction of the display; a second movable member disposed on a second side of the back surface of the display configured to be movable in the widthwise direction of the display; and a driver configured to move the first movable member and the second movable member. The first movable member and the second movable member are transformed between a straight state and a curved state in accordance with transformation of the display.

The driver may include: a cam disposed between a first end of the first movable member and a first end of the second movable member, and configured to move the first movable member and the second movable member in opposite directions; and a driving motor configured to move the cam.

The first movable member may include: a first cam part disposed at the first end of the first movable member configured to interact with the cam; and a first connection part disposed at a second end of the first movable member and connected to the display. The second movable member may include: a second cam part disposed at the first end of the second movable member configured to interact with the cam; and a second connection part disposed at a second end of the second movable member and connected to the display.

The first movable member and the second movable member may be formed of elastic materials.

The first movable member may include a plurality of slits formed on a back surface of the first movable member and spaced apart from each other along a widthwise direction of the display, and the second movable member may include a plurality of slits formed on a back surface of the second movable member and spaced apart from each other along a widthwise direction of the display.

The display apparatus may further include: a first guide rail disposed on the first side of the back surface of the display configured to guide a movement of the first movable member; and a second guide rail disposed on the second side of the back surface of the display configured to guide a movement of the second movable member.

The first guide rail and the second guide rail may be formed of elastic materials.

The first guide rail may include a plurality of slits formed on the back surface of the first guide rail and spaced apart from each other along a widthwise direction of the display, and the second guide rail may include a plurality of slits formed on the back surface of the second guide rail and spaced apart from each other along a widthwise direction of the display.

The display apparatus may further include: a guide frame having a rectangular ring shape and configured to support outer edges of the back surface of the display. The guide frame may include transformation guide units laterally extending at upper and lower portions of the display and connected to the first and second connection parts.

The display apparatus may further include: a stand configured support the display in a standing position on a horizontal plane; and a base member configured to support the display and fixed to the stand.

The base member may be integrally formed with the stand.

The base member may support a central portion of the display, the driver may mounted on the base member, and the first movable member and the second movable member may be installed on a first side and a second side of the base member, respectively.

The driver may include: a cam disposed between one end of the first movable member and one end of the second movable member, and configured to move the first movable member and the second movable member in opposite directions; and a driving motor configured to move the cam.

The display apparatus may further include: a controller configured to control the driving device in accordance with at least one of a content source for content displayed on the display, information received with the content, or information derived from the content.

The display apparatus may further include: a receiver configured to receive a user command, and the driver may move the first movable member and the second movable member in accordance with the received command.

The display apparatus may further include: a base member configured to support the display, the driver may be mounted on the base member, and the first movable member and the second movable member may be installed on a first side and a second side of the base member, respectively.

The display may be configured to be transformed within a predetermined range of a radius of curvature of the display between the flat state and a fully curved state.

In accordance with another aspect of one or more exemplary embodiments, a display apparatus includes: a display configured to be transformed between a flat state and a curved state in which both lateral ends of the display protrude; a stand configured to support the display in a standing position on a horizontal plane; a base member connected to the stand and configured to support the display; a first movable member disposed on a first side of a back surface of the display configured to be movable in a widthwise direction of the display; a second movable member disposed on a second side of the back surface of the display configured to be movable in the widthwise direction of the display; and a driver configured to move the first movable member and the second movable member.

The first movable member and the second movable member may be configured to be transformed between a straight state and a curved state in accordance with a transformation of the display.

The first movable member and the second movable member may be formed of elastic materials.

The first movable member may include a plurality of slits formed on a back surface of the first movable member and spaced apart from each other along a widthwise direction of the display, and the second movable member may include a plurality of slits formed on a back surface of the second movable member and spaced apart from each other along a widthwise direction of the display.

The display apparatus may further include: a first guide rail disposed on the first side of the back surface of the display configured to guide a movement of the first movable member; and a second guide rail disposed on the second side of the back surface of the display configured to guide a movement of the second movable member.

The first guide rail and the second guide rail may be formed of elastic materials.

The first guide rail may include a plurality of slits formed on the back surface of the first guide rail and spaced apart from each other along a widthwise direction of the display, and the second guide rail may include a plurality of slits formed on the back surface of the second guide rail and spaced apart from each other along a widthwise direction of the display.

### BRIEF DESCRIPTION OF THE DRAWINGS

These and/or other aspects of one or more exemplary embodiments will become apparent and more readily appreciated from the following description, taken in conjunction with the accompanying drawings of which:

FIG. 1 is a perspective view illustrating a flat state of a display module of a display apparatus according to an exemplary embodiment;

FIG. 2 is a perspective view illustrating a curved state of a display module of a display apparatus according to an exemplary embodiment;

FIG. 3 is an exploded perspective view illustrating a display apparatus according to an exemplary embodiment;

FIG. 4 is a back perspective view illustrating operation of a driving device when a display module of a display apparatus according to an exemplary embodiment is in a flat state; and

FIG. 5 is a back perspective view illustrating operation of a driving device when a display module of a display apparatus according to an exemplary embodiment is in a curved state.

### DETAILED DESCRIPTION

Reference will now be made in detail to one or more exemplary embodiments, examples of which are illustrated in the accompanying drawings, wherein like reference numerals refer to like elements throughout.

Hereinafter, a display apparatus 1 according to an exemplary embodiment will be described in detail with reference to the drawings.

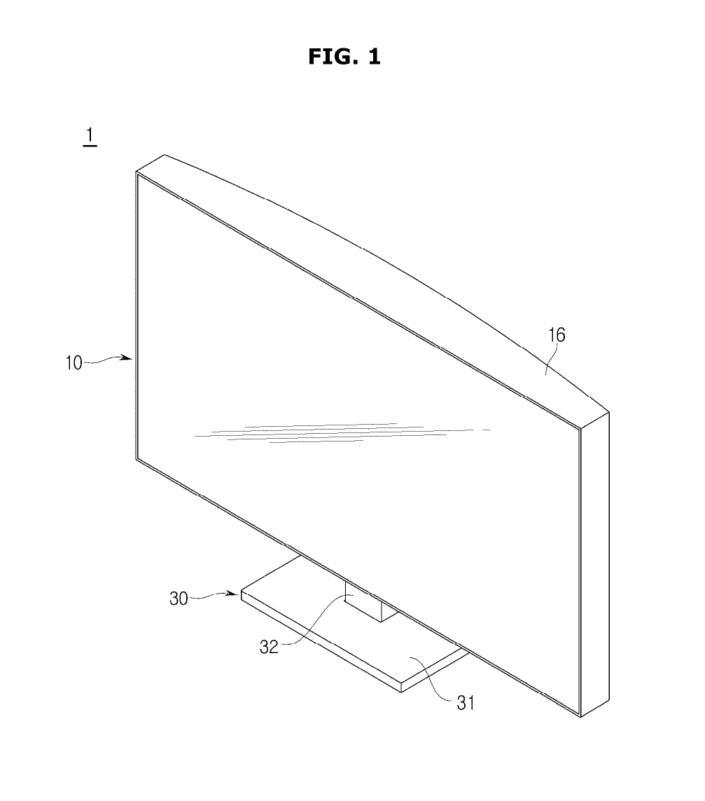

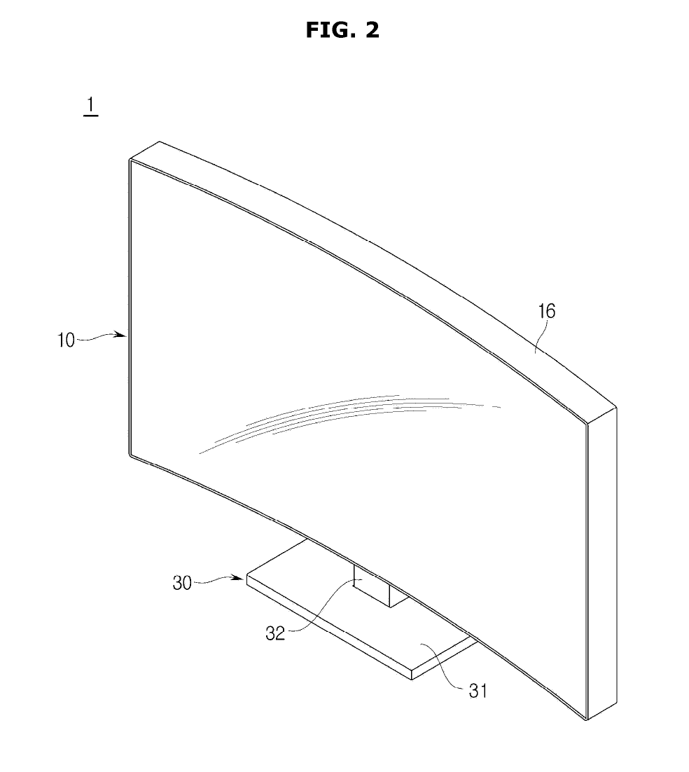

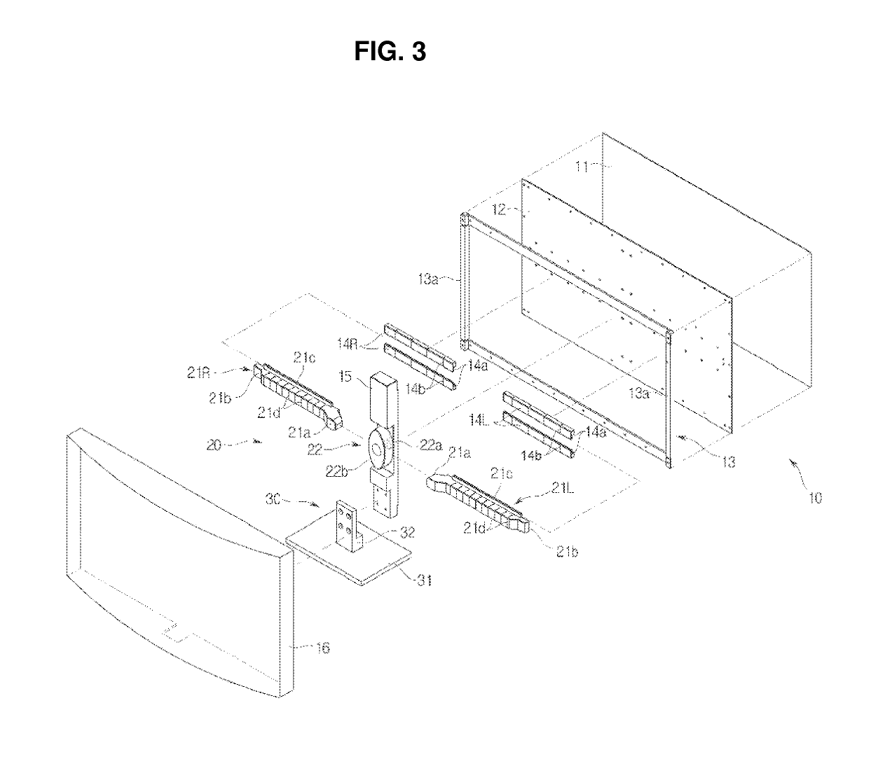

Referring to FIGS. 1 and 2, the display apparatus 1 includes a display module 10, i.e., a display, configured to display an image and transformable between a flat state and a curved state in which both side end portions thereof protrude forward, a driving device 20 (FIG. 3) configured to transform the display module 10 between the flat state and the curved state, and a stand 30 configured to keep the display module 10 in a standing position on a horizontal plane. Although the curved state is described as the end portions of the display module 10 protruding forward, alternatively, the end portions may protrude backwards, giving the display a convex shape. Further, the display module 10 may be transformable between a flat state, a convex curved state, and a concave curved state.

As illustrated in FIG. 3, the display module 10 includes a display panel 11 having a rectangular flat panel shape and for displaying a screen, a support panel 12 having a rectangular flat panel shape corresponding to the display panel 11 and supporting a back surface of the display panel 11, and a guide frame 13 having a rectangular ring shape to support outer edges of the back surface of the support panel 12 and to guide a transformation of the display module 10.

The guide frame 13 includes transformation guide units 14a protruding towards a back end of the display module 10 to which connection parts 21b of a first movable member 21R and a second movable member 21L are connected. Upper and lower transformation guide units 14a extend laterally so that an upper portion and a lower portion of the display module 10 may be simultaneously transformed.

The driving device 20 includes the first movable member 21R extending horizontally and mounted on one side of the back surface of the display module 10 and movable in a widthwise direction of the display module to move a first lateral end of the display module 10 forward and backward, the second movable member 21L extending horizontally and mounted on the other side of the back surface of the display module 10 and movable in the widthwise direction of the display module to move a second lateral end of the display module 10 forward and backward, and a driver 22, i.e., a driver, to move the first movable member 21R and the second movable member 21L.

The driver 22 includes a driving motor 22a that generates a rotation force and a cam 22b rotatably installed between one end of the first movable member 21R and one end of the second movable member 21L and that move the first movable member 21R and the second movable member 21L in opposite directions while rotating by a rotation force received from the driving motor 22a.

Cam parts 21a, which contact the cam 22a and interact with the cam 22b, are respectively disposed at ends of the first movable member 21R and the second movable member 21L located at or near central portions of the display module 10. The connection parts 21b, which are connected to the guide frame 13 and apply a force to the guide frame 13, are respectively disposed at the other ends of the first movable member 21R and the second movable member 21L located near sides of the display module 10.

The display module 10 includes a first guide rail 14R and a second guide rail 14L to guide the first movable member 21R and the second movable member 21L. The first guide rail 14R is disposed at one side of the back surface of the display module 10 to guide the movement of the first movable member 21R, and the second guide rail 14L is disposed at the other side of the back surface of the display module 10 to guide the movement of the second movable member 21L.

The first movable member 21R and the second movable member 21L respectively include a pair of upper and lower moving guide parts 21c extending laterally and guided by the first and second guide rails 14R and 14L.

The first guide rail 14R includes a pair of upper and lower first guide rails 14R spaced apart from each other such that the first movable member 21R is movably installed between the two first guide rails 14R. The second guide rail 14L includes a pair of upper and lower second guide rails 14L spaced apart from each other such that the second movable member 21L is movably installed between the two second guide rails 14L. The pair of first guide rails 14R and the pair of second guide rails 14L respectively have guide grooves 14a into which the moving guide parts 21c are movably installed.

The first movable member 21R, the second movable member 21L, the pair of first guide rails 14R, and the pair of second guide rails 14L are formed of elastic materials and may be transformed between a straight state and a curved state as the display module 10 is transformed between the flat state and the curved state.

Also, slits 21d and 14b are formed on the back surface of each of the first movable member 21R, the second movable member 21L, the pair of first guide rails 14R, and the pair of second guide rails 14L to facilitate the transformation. The slits 21d and 14b extend vertically and are spaced apart from each other along the widthwise direction on the back surface of each of the first movable member 21R, the second movable member 21L, the pair of first guide rails 14R, and the pair of second guide rails 14L. The slits may provide increased flexibility to the first movable member 21R, the second movable member 21L, the pair of first guide rails 14R, and the pair of second guide rails 14L.

A base member 15 that is connected to the stand 30 and supports the display module 10 is mounted on the back surface of the display module 10. The base member 15 has a vertically extending bar shape and supports a central portion of the display module 10.

The base member 15 is provided with the aforementioned driver 22, i.e., the driving motor 22a and the cam 22b, and the first movable member 21R and the second movable member 21L are symmetrically installed on either side of the base member 15. Thus, moving of the first movable member 21R and the second movable member 21L and transformation of the display module 10 are performed with respect to the base member 15.

The cam 22b has an oval shape and contacts the cam parts 21a of the first movable member 21R and the second movable member 21L while rotating, thereby pushing the first movable member 21R and the second movable member 21L toward the outer edges of the display module 10.

The stand 30 includes a support part 31 supported by the floor and a neck part 32 extending upward from the support part 31. The base member 15 is connected to an upper portion of the neck part 32.

Also, the display apparatus 1 includes a case 16 defining the back surface thereof. The case 16 covers the back surfaces of the display module 10 and the driving device 20 and may be deformable in accordance with the transformation of the display module 10.

Hereinafter, operation of the display apparatus 1 will be described in detail with reference to the drawings.

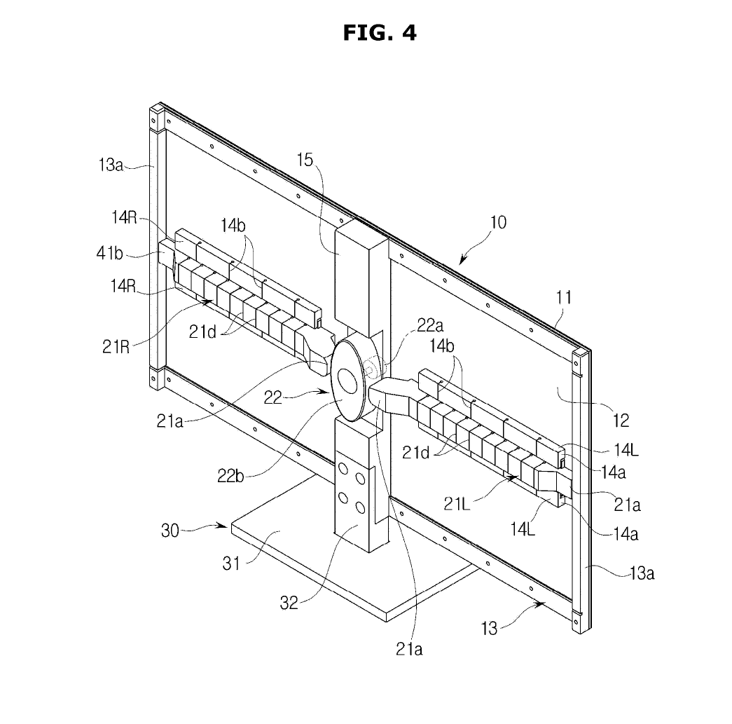

First, as illustrated in FIG. 4, when the display module 10 is in a flat state, a short axis of the oval-shaped cam 22b faces the cam parts 21a of the first movable member 21R and the second movable member 21L.

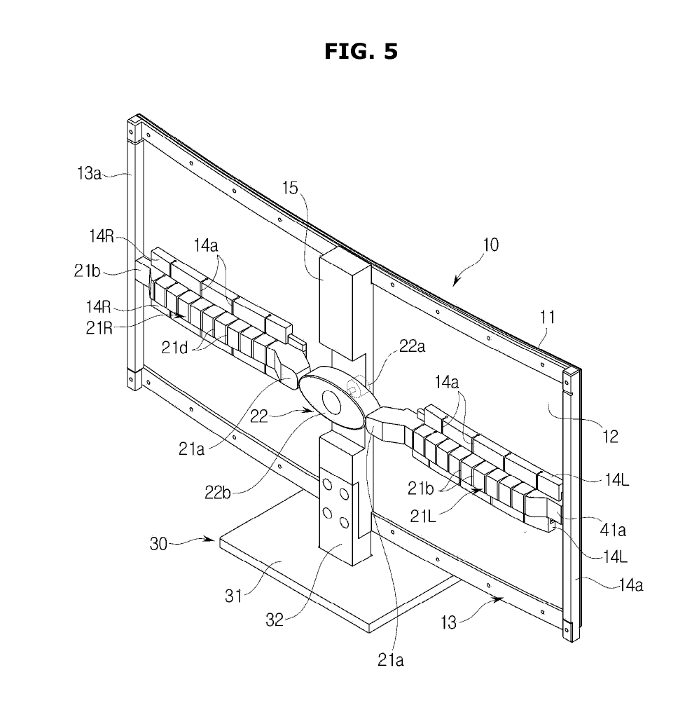

When the cam 22b rotates by 90 degrees by the driving motor 22a in accordance with a user's command, as illustrated in FIG. 5, a long axis of the cam 22b moves to a position corresponding to the cam parts 21a of the first movable member 21R and the second movable member 21L to contact the cam parts 21a of the first movable member 21R and the second movable member 21L, thereby pushing the first movable member 21R and the second movable member 21L toward the outer edges of the display module 10.

The first movable member 21R and the second movable member 21L are connected to the transformation guide units 14a of the guide frame 13 via the connection parts 21b, and the display module 10 is transformable. Accordingly, as the first movable member 21R and the second movable member 21L move, both lateral ends of the display module 10 move forward. In this case, the central portion of the display module 10 does not move since it is supported by the base member 15, and only the lateral ends of the display module 10 move forward, so that the display module 10 is in a curved state as illustrated in FIG. 5.

In addition, since the first movable member 21R, the second movable member 21L, the pair of first guide rails 14R, and the pair of second guide rails 14L are respectively formed of elastic materials and have a plurality of slits 21d and 14b, they are easily transformed. Thus, as the display module 10 is transformed into the curved surface, the first movable member 21R, the second movable member 21L, the pair of first guide rails 14R, and the pair of second guide rails 14L are transformed to correspond to the display module 10 in the curved state.

In this case, transformation of the first movable member 21R, the second movable member 21L, the pair of first guide rails 14R, and the pair of second guide rails 14L into the curved state may be facilitated by the slits 21d and 14b disposed therein.

The driving device 20 according to an exemplary embodiment includes one first movable member 21R and one second movable member 21L. However, the driving device 20 is not limited thereto and may also include a plurality of first movable members 21R and a plurality of second movable members 21L, if required.

The display apparatus 1 may include buttons mounted on a controller, a remote control, or the display apparatus 1 for controlling the driving device 20, and a user may control the transformation of the display module 10 between the flat state and the curved state by manipulating the buttons. The display apparatus 1 may include a receiver, i.e., an input unit or an input/output (I/O) interface, configured to receive commands for controlling the driving device.

Alternatively, the display module 10 may be automatically transformed into the flat state or the curved state by the driving device 20 in accordance with a content type to be displayed on the display module 10.

For example, when information indicating that a content to be displayed on the display module 10 is news is input to the display apparatus 1, the driving device 20 may transform the display module 10 into the flat state by the driving device 20 or maintain the flat state. When information indicating that the content to be displayed on the display apparatus 1 is a movie is input to the display apparatus 1, the driving device 20 may transform the display module 10 into the curved state or maintain the curved state.

Information regarding the type of content may be input by a user via buttons or may be received from an image sender, such as a broadcaster, together with image signals. The information may also be determined from a content source or derived by analyzing the content.

Alternatively, the display module 10 may be automatically transformed into the flat state or the curved state in accordance with a content source.

The display module 10 may include a controller or a processor that controls the driving device 20 to change or maintain the state of the display module in accordance with a user command, or automatically based on the content.

In addition, the display module 10 according to an exemplary embodiment is transformed into a flat state or a curved state having a predetermined radius of curvature, without being limited thereto. The display module 10 may be transformed within a predetermined range of the radius of curvature according to a user's selection, or may be transformed in a multi-stage manner. That is, when the user presses a button, the radius of curvature of the display module 10 may be continuously changed in proportion to a pressing time, or the radius of curvature of the display module 10 may be changed in a multi-stage manner in proportion to a number of button presses or a selection of a user.

The base member 15 according to an exemplary embodiment has a rectangular bar shape. However, the shape of the base member 15 is not limited thereto, and the base member 15 may have various shapes, such as a rectangular flat panel shape, on which the driver 22 is mounted to support the central axis of the display module 10.

The base member 15 is separate from the stand 30 and is fixed to the neck part 32 of the stand 30. However, exemplary embodiments are not limited thereto, and the base member 15 and the stand 30 may also be integrally formed.

According to an exemplary embodiment, the base member 15 is connected to the stand 30 such that the display apparatus 1 may stand on the horizontal plane via the stand 30. However, exemplary embodiments are not limited thereto, and the base member 15 may also be connected to a wall-mounting bracket instead of the stand 30 such that the display apparatus 1 may be mounted on a wall.

The cam 22b is driven by a driving motor 22a. However, exemplary embodiments are not limited thereto, and the cam 22b may be driven by a user.

The oval shaped cam 22b moves the first movable member 21R and the second movable member 21L in opposite directions while rotating. However, exemplary embodiments are not limited thereto, and the first movable member 21R and the second movable member 21L may be moved by alternative structures.

As is apparent from the above description, the display module of the display apparatus may be transformed by the driving device to be selectively used in either a flat state or a curved state.

Although a few exemplary embodiments have been shown and described, it would be appreciated by those skilled in the art that changes may be made in these embodiments without departing from the principles and spirit of the disclosure, the scope of which is defined in the claims and their equivalents.

What is claimed is:

1. A display apparatus comprising:
a display configured to be transformed between a flat state and a curved state in which both lateral ends of the display protrude; and
a driving device configured to transform the display between the flat state and the curved state,
wherein the driving device comprises:
a first movable member disposed on a first side of a back surface of the display configured to be movable in a widthwise direction of the display;
a second movable member disposed on a second side of the back surface of the display configured to be movable in the widthwise direction of the display; and
a driver configured to move the first movable member and the second movable member, and
wherein the first movable member and the second movable member are transformed between a straight state and a curved state in accordance with transformation of the display.

2. The display apparatus according to claim 1, wherein the driver comprises:
a cam disposed between a first end of the first movable member and a first end of the second movable member, and configured to move the first movable member and the second movable member in opposite directions; and
a driving motor configured to move the cam.

3. The display apparatus according to claim 2, wherein the first movable member comprises:
a first cam part disposed at the first end of the first movable member configured to interact with the cam; and
a first connection part disposed at a second end of the first movable member and connected to the display; and
wherein the second movable member comprises:
a second cam part disposed at the first end of the second movable member configured to interact with the cam; and
a second connection part disposed at a second end of the second movable member and connected to the display.

4. The display apparatus according to claim 1, wherein the first movable member and the second movable member are formed of elastic materials.

5. The display apparatus according to claim 4, wherein the first movable member comprises a plurality of slits formed on a back surface of the first movable member and spaced apart from each other along a widthwise direction of the display, and
wherein the second movable member comprises a plurality of slits formed on a back surface of the second movable member and spaced apart from each other along a widthwise direction of the display.

6. The display apparatus according to claim 2, further comprising:
a first guide rail disposed on the first side of the back surface of the display configured to guide a movement of the first movable member; and
a second guide rail disposed on the second side of the back surface of the display configured to guide a movement of the second movable member.

7. The display apparatus according to claim 6, wherein the first guide rail and the second guide rail are formed of elastic materials.

8. The display apparatus according to claim 7, wherein the first guide rail comprises a plurality of slits formed on the back surface of the first guide rail and spaced apart from each other along a widthwise direction of the display, and
wherein the second guide rail comprises a plurality of slits formed on the back surface of the second guide rail and spaced apart from each other along a widthwise direction of the display.

9. The display apparatus according to claim 3, further comprising:
a guide frame having a rectangular ring shape and configured to support outer edges of the back surface of the display,
wherein the guide frame comprises transformation guide units laterally extending at upper and lower portions of the display and connected to the first and second connection parts.

10. The display apparatus according to claim 1, further comprising:
a stand configured support the display in a standing position on a horizontal plane; and
a base member configured to support the display and fixed to the stand.

11. The display apparatus according to claim 10, wherein the base member is integrally formed with the stand.

12. The display apparatus according to claim 10, wherein the base member supports a central portion of the display,
wherein the driver is mounted on the base member, and
wherein the first movable member and the second movable member are installed on a first side and a second side of the base member, respectively.

13. The display apparatus according to claim 12, wherein the driver comprises:
a cam disposed between one end of the first movable member and one end of the second movable member, and configured to move the first movable member and the second movable member in opposite directions; and
a driving motor configured to move the cam.

14. A display apparatus comprising:
a display configured to be transformed between a flat state and a curved state in which both lateral ends of the display protrude;
a stand configured to support the display in a standing position on a horizontal plane;
a base member connected to the stand and configured to support the display;
a first movable member disposed on a first side of a back surface of the display configured to be movable in a widthwise direction of the display;
a second movable member disposed on a second side of the back surface of the display configured to be movable in the widthwise direction of the display; and
a driver configured to move the first movable member and the second movable member.

15. The display apparatus according to claim 14, wherein the first movable member and the second movable member are configured to be transformed between a straight state and a curved state in accordance with a transformation of the display.

16. The display apparatus according to claim 15, wherein the first movable member and the second movable member are formed of elastic materials.

17. The display apparatus according to claim 16, wherein the first movable member comprises a plurality of slits formed on a back surface of the first movable member and spaced apart from each other along a widthwise direction of the display, and
wherein the second movable member comprises a plurality of slits formed on a back surface of the second movable member and spaced apart from each other along a widthwise direction of the display.

18. The display apparatus according to claim 14, further comprising:
a first guide rail disposed on the first side of the back surface of the display configured to guide a movement of the first movable member; and
a second guide rail disposed on the second side of the back surface of the display configured to guide a movement of the second movable member.

19. The display apparatus according to claim 18, wherein the first guide rail and the second guide rail are formed of elastic materials.

20. The display apparatus according to claim 19, wherein the first guide rail comprises a plurality of slits formed on the back surface of the first guide rail and spaced apart from each other along a widthwise direction of the display, and
wherein the second guide rail comprises a plurality of slits formed on the back surface of the second guide rail and spaced apart from each other along a widthwise direction of the display.

21. The display apparatus according to claim 1, further comprising:
a controller configured to control the driving device in accordance with at least one of a content source for content displayed on the display, information received with the content, or information derived from the content.

22. The display apparatus according to claim 1, further comprising:
a receiver configured to receive a user command,
wherein the driver moves the first movable member and the second movable member in accordance with the received command.

23. The display apparatus according to claim 1, further comprising:
a base member configured to support the display,
wherein the driver is mounted on the base member, and
wherein the first movable member and the second movable member are installed on a first side and a second side of the base member, respectively.

24. The display apparatus according to claim 1, wherein the display is configured to be transformed within a predetermined range of a radius of curvature of the display between the flat state and a fully curved state.
